(19) United States
(12) Patent Application Publication
(10) Pub. No.: US 2022/0271101 A1
(43) Pub. Date: Aug. 25, 2022

(54) DISPLAY DEVICE, DISPLAY PANEL, AND MANUFACTURING METHOD THEREOF

(71) Applicant: Shenzhen China Star Optoelectronics Semiconductor Display Technologies Co., Ltd., Shenzhen (CN)

(72) Inventor: Yifei BING, Shenzhen (CN)

(21) Appl. No.: 16/622,923

(22) PCT Filed: Nov. 25, 2019
(86) PCT No.: PCT/CN2019/120587

§ 371 Date: Dec. 16, 2019

(30) Foreign Application Priority Data
Nov. 15, 2019 (CN) 201911116280.1

(51) Int. Cl. H01L 27/32

(52) U.S. Cl. CPC H01L 27/3218; H01L 27/3246; H01L 2227/323

(57) ABSTRACT

The present invention provides a display panel including a pixel layer. The pixel layer includes a plurality of pixel units having a regular M polygon. Each inner angle of the regular M polygon is m, wherein

$$m = \frac{( M - 2 ) * π}{M} .$$

Each of the pixel units includes M sub-pixels respectively disposed at M corners of the regular M polygon. A gap is disposed between the two adjacent sub-pixels,

wherein M is a positive integer greater than 2, and

$$\frac{2 π}{m}$$

is a positive integer.

Each of the sub-pixels in a same pixel unit is included in a sub-pixel group. The sub-pixel group is a center-symmetrical figure. The sub-pixel group includes

$$\frac{2 π}{m}$$

sub-pixels that have the same color and are disconnected from each other. Any two of the sub-pixels in the sub-pixel group are symmetrical about a corresponding symmetry axis, and each the symmetry axis passes through a center of the sub-pixel group.

This application claims filed Nov. 15, 2019 Chinese Patent Application No. 201911116280.1, entitled “Display device, display panel, and manufacturing method thereof” in Chinese Priority Patent Application, the entire content of which is incorporated by reference in the present application.

### FIELD OF INVENTION

The invention relates to the technical field of display, in particular to a manufacture of a display device, and specifically relates to a display device, a display panel, and a manufacturing method thereof.

### BACKGROUND OF INVENTION

An organic light emitting diode (OLED) is a new type of current semiconductor light-emitting devices, which belongs to autonomous light-emitting technologies. Compared with traditional LCD display panels, OLED display panels have advantages of fast response time, high contrast, and wide viewing angles.

In the prior art, when making pixel layers, in order to avoid color mixing between different color solutions, it is usually necessary to prepare a sufficiently large groove to accommodate the above solutions. However, larger groove sizes limit the number of pixels of the OLED display panels, which causing a problem that resolutions of the OLED display panels are lower.

Therefore, it is necessary to provide a display device, a display panel, and a manufacturing method thereof, in order to maintain sizes of current grooves and solve problems of low resolutions in the current OLED display panels.

### TECHNICAL PROBLEM

The present invention provides a display device, a display panel, and a manufacturing method thereof, in order to maintain sizes of current grooves and solve problems of low resolutions in the current OLED display panels.

### TECHNICAL SOLUTION

The present invention provides a display panel, comprising:

a substrate and a pixel layer disposed on the substrate;

wherein the pixel layer comprises a plurality of pixel units, each of the pixel units is a regular M polygon, and each inner angle of the regular M polygon is m, wherein

$$m = \frac{( M - 2 ) * π}{M} ;$$

each of the pixel units comprise M sub-pixels, and the M sub-pixels are respectively disposed at M corners of the regular M polygon; colors of the M sub-pixels are different, shapes and sizes of the M sub-pixels are the same, and a gap is disposed between the two adjacent sub-pixels, wherein M is a positive integer greater than 2, and

$$\frac{2 π}{m}$$

is a positive integer;

wherein each of the sub-pixels in a same pixel unit is included in a sub-pixel group, and the sub-pixel group is a center-symmetrical figure; the sub-pixel group comprise

$$\frac{2 π}{m}$$

sub-pixels, any two of the sub-pixels in the sub-pixel group are symmetrical about a corresponding symmetry axis, each the symmetry axis passes through a center of the sub-pixel group, and the

$$\frac{2 π}{m}$$

sub-pixels in each the sub-pixel group have the same color and are disconnected from each other.

In an embodiment, the M is 3, each of the pixel units is a regular triangle, each of the pixel units comprises three of the sub-pixels, and the three sub-pixels are respectively disposed at three corners of the regular triangle; and wherein the sub-pixel group comprises six of the sub-pixels.

In an embodiment, the M is 4, each of the pixel units is a square, each of the pixel units comprises four of the sub-pixels, and the four sub-pixels are respectively disposed at four corners of the square; and wherein the sub-pixel group comprises four of the sub-pixels.

In an embodiment, the M is 6, each of the pixel units is a regular hexagon, each of the pixel units comprises six of the sub-pixels, and the six sub-pixels are respectively disposed at six corners of the regular hexagon; and wherein the sub-pixel group comprises three of the sub-pixels.

In an embodiment, the display panel further comprises an anode layer disposed between the substrate and the pixel layer, wherein the anode layer comprises a plurality of anode portions, and the anode portions are disposed opposite to the sub-pixels.

In an embodiment, the display panel further comprises a pixel definition layer disposed on the substrate, wherein the pixel definition layer comprises a plurality of first pixel definition portions, and the first pixel definition portions are disposed between the two adjacent anode portions in the same sub-pixel group.

In an embodiment, a material of the first pixel defining portion is an insulating material.

In an embodiment, the pixel definition layer further comprises a plurality of second pixel definition portions, and the second pixel definition portions are disposed between the two adjacent sub-pixel groups.

The present invention further provides a display device, comprising:

a display panel, wherein the display panel comprises:

a substrate and a pixel layer disposed on the substrate;

wherein the pixel layer comprises a plurality of pixel units, each of the pixel units is a regular M polygon, and each inner angle of the regular M polygon is m,

$$m = \frac{( M - 2 ) * π}{M} ;$$

wherein each of the pixel units comprise M sub-pixels, and the M sub-pixels are respectively disposed at M corners of the regular M polygon; colors of the M sub-pixels are different, shapes and sizes of the M sub-pixels are the same, and a gap is disposed between the two adjacent sub-pixels, wherein M is a positive integer greater than 2, and

$$\frac{2 π}{m}$$

is a positive integer;

wherein each of the sub-pixels in a same pixel unit is included in a sub-pixel group, and the sub-pixel group is a center-symmetrical figure; the sub-pixel group comprise

$$\frac{2 π}{m}$$

sub-pixels, any two of the sub-pixels in the sub-pixel group are symmetrical about a corresponding symmetry axis, each the symmetry axis passes through a center of the sub-pixel group, and the

$$\frac{2 π}{m}$$

sub-pixels in each the sub-pixel group have the same color and are disconnected from each other.

In an embodiment, the M is 3, each of the pixel units is a regular triangle, each of the pixel units comprises three of the sub-pixels, and the three sub-pixels are respectively disposed at three corners of the regular triangle; and wherein the sub-pixel group comprises six of the sub-pixels.

In an embodiment, the M is 4, each of the pixel units is a square, each of the pixel units comprises four of the sub-pixels, and the four sub-pixels are respectively disposed at four corners of the square; and wherein the sub-pixel group comprises four of the sub-pixels.

In an embodiment, the M is 6, each of the pixel units is a regular hexagon, each of the pixel units comprises six of the sub-pixels, and the six sub-pixels are respectively disposed at six corners of the regular hexagon; and wherein the sub-pixel group comprises three of the sub-pixels.

In an embodiment, the display device further comprises an anode layer disposed between the substrate and the pixel layer, wherein the anode layer comprises a plurality of anode portions, and the anode portions are disposed opposite to the sub-pixels.

In an embodiment, the display device further comprises a pixel definition layer disposed on the substrate, wherein the pixel definition layer comprises a plurality of first pixel definition portions, and the first pixel definition portions are disposed between the two adjacent anode portions in the same sub-pixel group.

In an embodiment, a material of the first pixel defining portion is an insulating material.

In an embodiment, the pixel definition layer further comprises a plurality of second pixel definition portions, and the second pixel definition portions are disposed between the two adjacent sub-pixel groups.

The present invention further provides a manufacturing method of a display panel, comprising following steps of:

providing a substrate; and

forming a pixel layer disposed on the substrate;

wherein the pixel layer comprises a plurality of pixel units, each of the pixel units is a regular M polygon, and each inner angle of the regular M polygon is m, wherein

$$m = \frac{( M - 2 ) * π}{M} ;$$

each of the pixel units comprise M sub-pixels, and the M sub-pixels are respectively disposed at M corners of the regular M polygon; colors of the M sub-pixels are different, shapes and sizes of the M sub-pixels are the same, and a gap is disposed between the two adjacent sub-pixels, wherein M is a positive integer greater than 2, and

$$\frac{2 π}{m}$$

is a positive integer;

wherein each of the sub-pixels in a same pixel unit is included in a sub-pixel group, and the sub-pixel group is a center-symmetrical figure; the sub-pixel group comprise

$$\frac{2 π}{m}$$

sub-pixels, any two of the sub-pixels in the sub-pixel group are symmetrical about a corresponding symmetry axis, each the symmetry axis passes through a center of the sub-pixel group, and the

$$\frac{2 π}{m}$$

sub-pixels in each the sub-pixel group have the same color and are disconnected from each other.

In an embodiment, before the step of forming the pixel layer disposed on the substrate further comprises:

forming an anode layer on the substrate, wherein the anode layer is disposed between the substrate and the pixel layer, the anode layer comprises a plurality of anode portions, and the anode portions are disposed opposite to the sub-pixels.

### BENEFICIAL EFFECT

The beneficial effect of the present invention is: by disposing a pixel unit having a regular M polygon, and each inner angle of the regular M polygon is m, wherein

$$m = \frac{( M - 2 ) * π}{M} .$$

Each of the pixel units includes M sub-pixels respectively disposed at M corners of the regular M polygon. Colors of the M sub-pixels are different, shapes and sizes of the M sub-pixels are the same, and a gap is disposed between the two adjacent sub-pixels, wherein M is a positive integer greater than 2, and

$$\frac{2 π}{m}$$

is a positive integer. Each of the sub-pixels in a same pixel unit is included in a sub-pixel group, and the sub-pixel group is a center-symmetrical figure. The sub-pixel group comprise

$$\frac{2 π}{m}$$

sub-pixels, any two of the sub-pixels in the sub-pixel group are symmetrical about a corresponding symmetry axis, each the symmetry axis passes through a center of the sub-pixel group, and the

$$\frac{2 π}{m}$$

sub-pixels in each the sub-pixel group have the same color and are disconnected from each other. That is, by splitting multiple sub-pixels in the same sub-pixel group, and then recombining the multiple sub-pixels in respective directions into corresponding multiple pixel units, the number of the pixel units can be 3 to 6 times the corresponding number in the prior art, so while maintaining sizes of current grooves, resolutions of display panels can be improved.

### DESCRIPTION OF DRAWINGS

The invention is further illustrated by the following figures. It should be noted that the drawings in the following description are only for illustrating some embodiments of the invention, and that other drawings can be obtained by those skilled in the art without inventive effort.

FIG. 1 is a schematic cross-sectional view of a display panel according to an embodiment of the invention.

FIG. 2 is a schematic top view of the display panel according to the embodiment of the present invention.

FIG. 3 is a schematic top view of another display panel according to the embodiment of the invention.

FIG. 4 is a schematic top view of another display panel according to the embodiment of the present invention.

FIG. 5 is a flowchart of a manufacturing method of the display panel according to the embodiment of present invention.

### DETAILED DESCRIPTION OF PREFERRED EMBODIMENTS

The technical solution in the embodiments of the present invention will be clearly and completely described below with reference to the accompanying drawings in the embodiments of the present invention. It is to be understood that the described embodiments are merely exemplary of the invention, and not restrictive of the full scope of the invention. All other embodiments, which can be obtained by a person skilled in the art without inventive step based on the embodiments of the present invention, are within the scope of the present invention.

In the description of the present invention, it is to be understood that the terms “upper”, “lower”, “left”, “right”, etc. indicate orientations or positional relationships based on those shown in the drawings, for example, where “upper” is only a surface above an object, specifically refers to a surface directly above, obliquely above, or above, as long as it is above the object level, and the above orientations or positional relationships are only for convenience of describing the present invention and simplifying the description, but do not indicate or imply that the device or element referred to must have a particular orientation, be constructed and operated in a particular orientation, and thus should not be construed as limiting the present invention.

It should be noted that the term “length” is a neutral word and does not indicate a bias toward long or short, but merely indicates that a reference value exists, and that no numerical value is determined, which may be practical.

In addition, it should be noted that the drawings only provide the structures and steps which are closely related to the present invention, and some details which are not related to the present invention are omitted, so as to simplify the drawings and make the invention clear, but not to show that the actual device and method are the same as the drawings and are not to be taken as the limitation of the actual device and method.

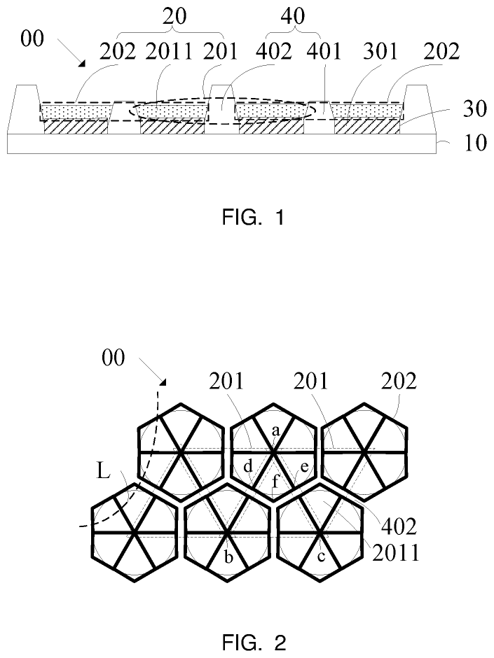

The present invention provides a display panel comprising the embodiments as shown in FIG. 1 to FIG. 3 and combinations of the embodiments.

In an embodiment, as shown in FIG. 1, the display panel 00 comprises a substrate 10 and a pixel layer 20 disposed on the substrate 10. FIG. 1 can be understood as a cross-sectional view along a line L in FIG. 2. As shown in FIG. 2 to FIG. 4, the pixel layer 20 comprises a plurality of pixel units 201, each of the pixel units 201 is a regular M polygon, and each inner angle of the regular M polygon is m, wherein

$$m = \frac{( M - 2 ) * π}{M} .$$

Each of the pixel units 201 comprise M sub-pixels 2011, and the M sub-pixels 2011 are respectively disposed at M corners of the regular M polygon. Colors of the M sub-pixels 2011 are different, shapes and sizes of the M sub-pixels 2011 are the same, and a gap is disposed between the two adjacent sub-pixels 2011, wherein M is a positive integer greater than 2, and

$$\frac{2 π}{m}$$

is a positive integer. Each of the sub-pixels 2011 in a same pixel unit 201 is included in a sub-pixel group 202, and the sub-pixel group 202 is a center-symmetrical figure. The sub-pixel group 202 comprise

$$\frac{2 π}{m}$$

sub-pixels 2011. Any two of the sub-pixels 2011 in the sub-pixel group 202 are symmetrical about a corresponding symmetry axis 2021. Each the symmetry axis 2021 passes through a center of the sub-pixel group 202. The

$$\frac{2 π}{m}$$

sub-pixels 2011 in each the sub-pixel group 202 have the same color and are disconnected from each other. From the observation of FIG. 2 to FIG. 4, it can be seen that: each sub-pixel 2011 sequentially rotates clockwise or counterclockwise by m around a corresponding vertex to form

$$( \frac{2 π}{m} - 1 )$$

sub-pixels 2011 with the same color as the sub-pixels 2011. The

$$( \frac{2 π}{m} - 1 )$$

sub-pixels 2011 collectively form the sub-pixel group 202, and the colors of the sub-pixel groups 202 disposed at the corners of the same pixel unit 201 are different from each other.

A material of each the sub-pixel 2011 can be a hydrophilic organic light-emitting material. Specifically, the sub-pixel 2011 may be formed by sequentially depositing and drying a hydrophilic organic light emitting solution, or by inkjet printing.

Specifically, the above description may include, but is not limited to, the following examples.

In an embodiment, as shown in FIG. 2, the M may be 3. each of the pixel units 201 is a regular triangle. Each inner angle of the regular triangle is

$$\frac{π}{6} .$$

Each of the pixel units 201 comprises three of the sub-pixels 2011, and the three sub-pixels 2011 are respectively disposed at three corners of the regular triangle. The sub-pixel group 202 comprises six of the sub-pixels 2011.

The colors of the three sub-pixels 2011 may be any three colors of red, green, blue, and yellow, respectively.

Observing FIG. 2, it can be found that each of the sub-pixels 2011 is sequentially rotated clockwise or counter-clockwise by

$$\frac{π}{3}$$

around the corresponding vertex to form five sub-pixels 2011 having the same color as the sub-pixel 2011, and the six sub-pixels 2011 collectively constitute the sub-pixel group 202.

For example, suppose that the pixel unit 201 with a regular triangle having three vertices a, b, and c. Take a geometric shape of one of the sub-pixels 2011 as an example: It can take two points d and e on two lines ab and ac that intersect at point a. Starting from the two points d and e, making at least one curve or at least one straight line into the pixel unit 201 respectively, and the at least one curve or at least one straight line is connected to form a connection line de. The lines ad, ae, and the connection line de together form an outline of the sub-pixel 2011. It should be noted that a length of the line ad or ae should be less than half of the line ab or ac, respectively, to ensure that there is a gap between the two adjacent sub-pixels 2011 in the same pixel unit 201, thereby preventing color mixing.

Further, the lengths of the lines ad and ae may be equal. Furthermore, the sub-pixels 2011 may be fan-shaped. Since the inner angles of the pixel units 201 are all 60°, a central angle corresponding to the fan shape is 60°. A radius of a circle corresponding to the fan shape is the line ad or the line ae, that is, the fan-shaped sub-pixels 2011 may be shaped as a one-sixth circle. At this time, the sub-pixel group 202 is a circle having a radius equal to the line ad. Or points d and e on the circle can be used as tangent points respectively to make two corresponding tangents. The two corresponding tangents intersect at a point f, and the lines ad, df, fe, and ea together form the outline of the sub-pixel 2011. At this time, the sub-pixel group 202 is a regular hexagon with a side length equal to (2*df). It can be seen from FIG. 2 that a plurality of regular triangle-shaped pixel units 201 disposed in a same row are alternately arranged in a sequence of upwards and downwards according to their vertex angles.

It can be understood that after the two points d and e are determined, it is determined that the lines ad and ae are two boundaries of the sub-pixel 2011. Use the points d and e as two ends to form another boundary of the sub-pixel 2011. Since the three sub-pixels 2011 in the same pixel unit 201 have the same shape and size, another boundary should be within the boundary formed by the lines df and fe to prevent crossover between the three sub-pixels 2011 and color mixing.

It should be noted that, for the embodiment in FIG. 2, it is assumed that an area of each of the sub-pixel groups 202 is S. If three sub-pixel groups 202 with different colors are regarded as one complete pixel, and an area occupied by the complete pixels is (3*S). However, if the pixel unit 201 containing three colors of sub-pixels 2011 is taken as a complete pixel according to a division method in the embodiment, the area occupied by each complete pixel is

$$[ {3}^{*} ( \frac{1}{6} * S ) ] ,$$

Which is (0.5*S). That is, when a total size of the display panel 00 is constant, a solution of the embodiment is adopted. Ideally, the number of complete pixels can be increased to 6 times the original. However, for an actual rectangular pixel setting method, considering a loss of the sub-pixel group 202 at both ends of the display panel 00, the number of the complete pixels in the embodiment may be 5.49 times the number of complete pixels in the rectangular pixel setting method. The size of the rectangular pixels is equivalent to the size of the sub-pixel group 202.

For example, please refer to Table 1, where a “first mode” indicates the above-mentioned “setting method of the rectangular pixel”, and a “second mode” indicates the above-mentioned setting method of the pixel unit 201 in FIG. 2. A “panel size” includes a size of a diagonal of the panel and a resolution of the panel. “65” 4K “can indicate that a length of the diagonal of the panel is 65 inches, the number of pixels in a horizontal direction of the panel is 3840, and the number of pixels in a vertical direction is 2160. “55” 16K “can indicate that a length of the diagonal of the panel is 55 inches, the number of pixels in the horizontal direction of the panel is 15,360, and the number of pixels in the vertical direction is 8,640. A “number of pixels” means the number of pixels per inch. According to the Pythagorean theorem, taking the “first mode” as an example, for the diagonal of the panel, the number of pixels of the diagonal is \sqrt{3840²+2160²}, which is about 4406, and calculate that the number of pixels per inch on the diagonal is about 68 pixels. Similarly, the number of pixels per inch on the diagonal of the “second mode” is about 320 pixels. Therefore, with the arrangement in the embodiment, when the sizes in Table 1 are adopted, the number of pixels per inch can be approximately 320/68 times of the “arrangement of rectangular pixels,” which is about 4.7 times. The “number of pixels” in this paragraph refers to the number of “full pixels” in the previous paragraph.

TABLE 1

| | Size of the panel | Number of pixels |
|---|---|---|
| First mode | 65″ 4K | 68 |
| Second mode | 55″ 16K | 320 |

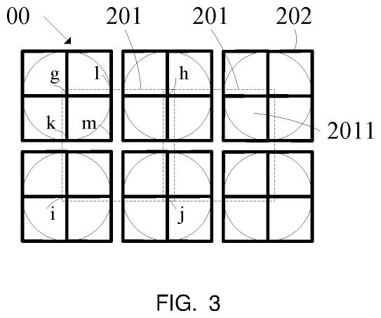

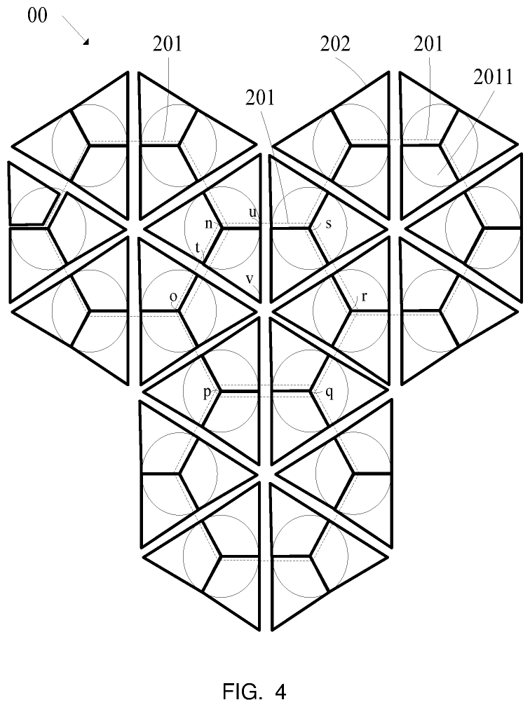

In an embodiment, as shown in FIG. 3, the M may be 4. each of the pixel units 201 is a square. Each inner angle of the square is

$$\frac{π}{2} .$$

Each of the pixel units 201 comprises four of the sub-pixels 2011, and the four sub-pixels 2011 are respectively disposed at four corners of the square. The sub-pixel group 202 comprises four of the sub-pixels 2011.

The colors of the four sub-pixels 2011 may be any three colors of red, green, blue, and yellow, respectively, and white.

Observing FIG. 3, it can be found that each of the sub-pixels 2011 is sequentially rotated clockwise or counter-clockwise by

$$\frac{π}{2}$$

around the corresponding vertex to form three sub-pixels 2011 having the same color as the sub-pixel 2011, and the four sub-pixels 2011 collectively constitute the sub-pixel group 202.

For example, suppose that the pixel unit 201 with the square having four vertices g, h, i, and j. Take a geometric shape of one of the sub-pixels 2011 as an example: It can take two points k and l on two lines gi and gh that intersect at point g. Starting from the two points k and l, making at least one curve or at least one straight line into the pixel unit 201 respectively, and the at least one curve or at least one straight line is connected to form a connection line kl. The lines gk, gl, and the connection lines kl together form the outline of the sub-pixel 2011. It should be noted that a length of the line gk or gl should be less than half of the line gi or gh, respectively, to ensure that there is a gap between the two adjacent sub-pixels 2011 in the same pixel unit 201, thereby preventing color mixing.

Further, the lengths of the lines gk and gl may be equal. Furthermore, the sub-pixels 2011 may be fan-shaped. Since the inner angles of the pixel units 201 are all 90°, a central angle corresponding to the fan shape is 90°. A radius of a circle corresponding to the fan shape is the line gk or the line gl, that is, the fan-shaped sub-pixels 2011 may be shaped as a quarter circle. At this time, the sub-pixel group 202 is a circle having a radius equal to the line gk. Or points k and l on the circle can be used as tangent points respectively to make two corresponding tangents. The two corresponding tangents intersect at a point m, and the square gkml form the outline of the sub-pixel 2011. At this time, the sub-pixel group 202 is a square with a side length equal to (2*ml). It can be seen from FIG. 3 that a plurality of square-shaped pixel units 201 disposed in a same row are alternately arranged in a direction in which any one side thereof faces upward.

It can be understood that after the two points k and l are determined, it is determined that the lines gk and gl are two boundaries of the sub-pixel 2011. Use the points k and l as two ends to form another boundary of the sub-pixel 2011. Since the four sub-pixels 2011 in the same pixel unit 201 have the same shape and size, another boundary should be within the boundary formed by the lines km and lm to prevent crossover between the four sub-pixels 2011 and color mixing.

It should be noted that, for the embodiment in FIG. 3, it is assumed that an area of each of the sub-pixel groups 202 is S₂. If four sub-pixel groups 202 with different colors are regarded as one complete pixel, and an area occupied by the complete pixels is (3*S₂). However, if the pixel unit 201 containing four colors of sub-pixels 2011 is taken as a complete pixel according to the division method in the embodiment, the area occupied by each complete pixel is

$$[ {4}^{*} ( \frac{1}{4} * {S}_{2} ) ] ,$$

Which is S₂. That is, when a total size of the display panel 00 is constant, a solution of the embodiment is adopted. Ideally, the number of complete pixels can be increased to 4 times the original.

In an embodiment, as shown in FIG. 4, the M may be 6. each of the pixel units 201 is a regular hexagon. Each inner angle of the regular hexagon is

$$\frac{2 π}{3} .$$

Each of the pixel units 201 comprises six of the sub-pixels 2011, and the six sub-pixels 2011 are respectively disposed at six corners of the regular hexagon. The sub-pixel group 202 comprises three of the sub-pixels 2011.

The colors of the six sub-pixels 2011 may be red, green, blue, yellow, white, and other colors, respectively. Of course, since the number of the sub-pixels 2011 included in the pixel unit 201 is large, the six sub-pixels 2011 may also comprise two red sub-pixels, two green sub-pixels, and two blue sub-pixels. Further, the colors of any three consecutive sub-pixels 2011 may be different.

Observing FIG. 4, it can be found that each of the sub-pixels 2011 is sequentially rotated clockwise or counter-clockwise by

$$\frac{2 π}{3}$$

around the corresponding vertex to form two sub-pixels 2011 having the same color as the sub-pixel 2011, and the three sub-pixels 2011 collectively constitute the sub-pixel group 202. The colors of the multiple sub-pixel groups 202 disposed at multiple corners of the same pixel unit 201 are also different.

For example, suppose that the pixel unit 201 with the regular hexagon having six vertices n, o, p, q, r, and s. Take a geometric shape of one of the sub-pixels 2011 as an example: It can take two points t and u on two lines no and ns that intersect at point n. Starting from the two points t and u, making at least one curve or at least one straight line into the pixel unit 201 respectively, and the at least one curve or at least one straight line is connected to form a connection line tu. The lines nt, nu, and the connection lines tu together form the outline of the sub-pixel 2011. It should be noted that a length of the line nt or nu should be less than half of the line no or ns, respectively, to ensure that there is a gap between the two adjacent sub-pixels 2011 in the same pixel unit 201, thereby preventing color mixing.

Further, the lengths of the lines nt and nu may be equal. Furthermore, the sub-pixels 2011 may be fan-shaped. Since the inner angles of the pixel units 201 are all 120°, a central angle corresponding to the fan shape is 120°. A radius of a circle corresponding to the fan shape is the line nt or the line nu, that is, the fan-shaped sub-pixels 2011 may be shaped as a one-third circle. At this time, the sub-pixel group 202 is a circle having a radius equal to the line nt. Or points t and u on the circle can be used as tangent points respectively to make two corresponding tangents. The two corresponding tangents intersect at a point v, and the lines nt, tv, vu, and un form the outline of the sub-pixel 2011. At this time, the sub-pixel group 202 is a regular triangle with a side length equal to (2*tv). It can be seen from FIG. 4 that a plurality of regular hexagonal pixel units 201 arranged in a same row are arranged in a direction in which any one of the pixel units 201 is upward. The pixel units 201 of two adjacent columns are separated by half of the length of the pixel unit 201 along the longitudinal direction in the longitudinal direction.

It can be understood that after the two points t and u are determined, it is determined that the lines nt and nu are two boundaries of the sub-pixel 2011. Use the points t and u as two ends to form another boundary of the sub-pixel 2011. Since the three sub-pixels 2011 in the same pixel unit 201 have the same shape and size, another boundary should be within the boundary formed by the lines tv and vu to prevent crossover between the six sub-pixels 2011 and color mixing.

It should be noted that, for the embodiment in FIG. 4, it is assumed that an area of each of the sub-pixel groups 202 is S₃. If six sub-pixel groups 202 with different colors are regarded as one complete pixel, and an area occupied by the complete pixels is (6*S₃). However, if the pixel unit 201 containing six colors of sub-pixels 2011 is taken as a complete pixel according to the division method in the embodiment, the area occupied by each complete pixel is

$$[ {6}^{*} ( \frac{1}{3} * {S}_{3} ) ] ,$$

Which is (2*S₃). That is, when a total size of the display panel 00 is constant, a solution of the embodiment is adopted. Ideally, the number of complete pixels can be increased to 3 times the original.

In other embodiments, in the same pixel unit 201, at least one of the shapes and sizes of the plurality of sub-pixels 2011 may be different. That is, at least one of the shapes and the sizes of each of the sub-pixel groups 202 is different. For example, in the same pixel unit 201, a plurality of the sub-pixels 2011 may include only the sides of the pixel unit 201 and not the corners of the pixel unit 201. For another example, in the same pixel unit 201, the lengths of a plurality of the sub-pixels 2011 on the sides of the pixel unit 201 may be different. For another example, in the same pixel unit 201, the outline of the sub-pixel 2011 may include more than three sides of the pixel unit 201.

It should be noted that when the sub-pixel group 202 is circular, the diameter of the sub-pixel group 202 may be not less than 1 micrometer and not more than 1000 micrometers. Particularly, for the printing process, the diameter of the sub-pixel group 202 may be not less than 40 microns, and not more than 200 microns.

Specifically, for each side of each of the pixel units 201, the distance between two adjacent sub-pixels 2011 is not less than 5 microns, and not more than 200 microns.

In an embodiment, as shown in FIG. 1, the display panel 00 further comprises an anode layer 30. The anode layer 30 is disposed between the substrate 10 and the pixel layer 20. The anode layer 30 comprises a plurality of anode portions 301, and the anode portions 301 are disposed opposite to the sub-pixels 2011.

Wherein, the anode layer 30 may be formed through a process of physical vapor deposition-development-wet etching. A material of the anode layer 30 may be a reflective material or a transmissive material. Specifically, when the display panel 00 is a top emission type, the anode layer 30 is made of a reflective material. When the display panel 00 is a bottom emission type, the anode layer 30 is made of a transmissive material.

Further, the display panel 00 further comprises a thin film transistor layer, and the thin film transistor layer is disposed between the substrate 10 and the anode layer 30. The thin film transistor layer comprises a plurality of thin film transistor units, and the thin film transistor units are disposed opposite to the anode portion 301. Specifically, a source or a drain of each thin film transistor is connected to a corresponding anode portion 301, and a voltage of the source or the drain of each the thin film transistor is controlled through a gate line and a data line to control a corresponding voltage of the anode portion 301. It can be understood that a cathode layer may be further disposed above the pixel layer 20. The cathode layer has a predetermined voltage, and the voltage or the current of the corresponding sub-pixel 2011 can be controlled by a voltage difference between each the anode portion 301 and the cathode layer, so as to control a color of light of the corresponding sub-pixel 2011. That is, in the same sub-pixel group 202, the color of the light of each the sub-pixel 2011 is independently controlled by the voltage or current of the corresponding anode portion 301.

In an embodiment, as shown in FIG. 1, the display panel 00 further comprises a pixel definition layer 40. The pixel definition layer 40 is disposed on the substrate 10. The pixel definition layer 40 comprises a plurality of first pixel definition portions 401, and the first pixel definition portions 401 are disposed between the two adjacent anode portions 301 in the same sub-pixel group 202.

A material of the first pixel definition portion 401 is an insulating material. It can be understood that, since the anode portions 301 are made of conductive material and each of the sub-pixels 2011 in the sub-pixel group 202 belongs to different pixel units 201, the anode portions 301 for controlling each of the sub-pixels 2011 should be disconnected from each other, i.e., not conductive. That is, the material of the first pixel definition portion 401 may be an insulating material. Further, it can be found through experiments that as long as the first pixel definition portion 401 is ensured to have the insulating function, that is, the sub-pixels 2011 can control the corresponding voltage or current of the corresponding anode portion 301, even if the plurality of sub-pixels 2011 in the same sub-pixel group 202 are in contact with each other, the effect of emitting light individually by each sub-pixel 2011 is not affected. It is understood that, in order to ensure an integrity of each sub-pixel group 202 and to increase the area of the sub-pixels 2011, the upper surface of the first pixel definition portion 401 is not lower than the upper surface of the sub-pixels 2011, so that the sub-pixels 2011 in the same sub-pixel group 202 are in contact with each other. Furthermore, the first pixel definition portion 401 may be made of hydrophilic material, so that the sub-pixels 2011 in the same sub-pixel group 202 may be more coherent with each other.

In an embodiment, as shown in FIG. 1, the pixel definition layer 40 further comprises a plurality of second pixel definition portions 402, and the second pixel definition portions 402 are disposed between the two adjacent sub-pixel groups 202. It is understood that the plurality of second pixel definition portions 402 fill all gaps between the plurality of sub-pixel groups 202, and the second pixel definition portions 402 are used for dividing the sub-pixel groups 202 with different colors to prevent color mixing. Further, since the material of the sub-pixel group 202 is a hydrophilic material, the second pixel definition portions 402 may be made of an organic resin material having hydrophobicity.

In an embodiment, as shown in FIG. 1, a cross-sectional shape of the first pixel definition portion 401 and the second pixel definition portion 402 may be trapezoid, and a length of an upper base of the trapezoid is less than that of the lower base. Specifically, the inclination angles on both sides of the cross-sectional pattern of the first pixel definition portion 401 and the second pixel definition portion 402 may be set to 60° or less. Thus, when a liquid organic light-emitting solution is applied, the liquid organic light-emitting solution flows toward the anode portion 103 along the side surfaces of the first pixel definition portion 401 and the second pixel definition portion 402 corresponding thereto. When the organic light-emitting solution is coated thickly, the mutual color mixing and overflow between the adjacent organic light-emitting solutions with different colors can be avoided.

The present invention further provides a display device, which may comprise the display panel in the above embodiments.

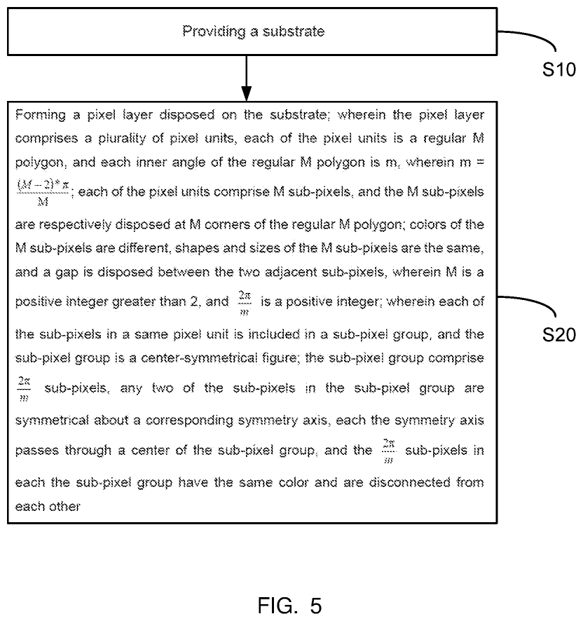

The present invention further provides a manufacturing method of a display panel, which comprises following steps of referring to FIG. 5 and combining the structural schematic views of FIG. 1 to FIG. 4.

S10: providing a substrate 10.

The substrate 10 may be an array substrate. The array substrate comprises a glass plate and a thin film transistor layer patterned on the glass plate. A material of the thin-film transistor layer may comprise, for example: preparation of at least one of low-temperature polycrystalline silicon material, oxide material or amorphous silicon material.

S20: forming a pixel layer 20 disposed on the substrate 10. The pixel layer 20 comprises a plurality of pixel units 201, each of the pixel units 201 is a regular M polygon, and each inner angle of the regular M polygon is m, wherein

$$m = \frac{( M - 2 ) * π}{M} ;$$

each of the pixel units 201 comprise M sub-pixels 2011, and the M sub-pixels 2011 are respectively disposed at M corners of the regular M polygon. Colors of the M sub-pixels 2011 are different, shapes and sizes of the M sub-pixels 2011 are the same, and a gap is disposed between the two adjacent sub-pixels 2011, wherein M is a positive integer greater than 2, and

$$\frac{2 π}{m}$$

is a positive integer. Each of the sub-pixels 2011 in a same pixel unit 201 is included in a sub-pixel group 202, and the sub-pixel group 202 is a center-symmetrical figure. The sub-pixel group 202 comprise

$$\frac{2 π}{m}$$

sub-pixels 2011. Any two of the sub-pixels 2011 in the sub-pixel group 202 are symmetrical about a corresponding symmetry axis 2021, each the symmetry axis 2021 passes through a center of the sub-pixel group 202, and the

$$\frac{2 π}{m}$$

sub-pixels 2011 in each the sub-pixel group 202 have the same color and are disconnected from each other.

A material of each the sub-pixel 2011 can be a hydrophilic organic light-emitting material. Specifically, the sub-pixel 2011 may be formed by sequentially depositing and drying a hydrophilic organic light emitting solution, or by inkjet printing.

Specifically, the above description may include, but is not limited to, the following examples.

In an embodiment, as shown in FIG. 2, the M may be 3. each of the pixel units 201 is a regular triangle. Each inner angle of the regular triangle is

$$\frac{π}{6} .$$

Each of the pixel units 201 comprises three of the sub-pixels 2011, and the three sub-pixels 2011 are respectively disposed at three corners of the regular triangle. The sub-pixel group 202 comprises six of the sub-pixels 2011.

The colors of the three sub-pixels 2011 may be any three colors of red, green, blue, and yellow, respectively.

Specifically, the relevant embodiments may be referred to the relevant description above with respect to FIG. 2.

In an embodiment, as shown in FIG. 3, the M may be 4. each of the pixel units 201 is a square. Each inner angle of the square is

$$\frac{π}{2} .$$

Each of the pixel units 201 comprises four of the sub-pixels 2011, and the four sub-pixels 2011 are respectively disposed at four corners of the square. The sub-pixel group 202 comprises four of the sub-pixels 2011.

The colors of the four sub-pixels 2011 may be any three colors of red, green, blue, and yellow, respectively, and white.

Specifically, the relevant embodiments may be referred to the relevant description above with respect to FIG. 3.

In an embodiment, as shown in FIG. 4, the M may be 6. each of the pixel units 201 is a regular hexagon. Each inner angle of the regular hexagon is

$$\frac{2 π}{3} .$$

Each of the pixel units 201 comprises six of the sub-pixels 2011, and the six sub-pixels 2011 are respectively disposed at six corners of the regular hexagon. The sub-pixel group 202 comprises three of the sub-pixels 2011.

The colors of the six sub-pixels 2011 may be red, green, blue, yellow, white, and other colors, respectively. Of course, since the number of the sub-pixels 2011 included in the pixel unit 201 is large, the six sub-pixels 2011 may also comprise two red sub-pixels, two green sub-pixels, and two blue sub-pixels. Further, the colors of any three consecutive sub-pixels 2011 may be different.

Specifically, the relevant embodiments may be referred to the relevant description above with respect to FIG. 4.

In other embodiments, in the same pixel unit 201, at least one of the shapes and sizes of the plurality of sub-pixels 2011 may be different. That is, at least one of the shapes and the sizes of each of the sub-pixel groups 202 is different. For example, in the same pixel unit 201, a plurality of the sub-pixels 2011 may include only the sides of the pixel unit 201 and not the corners of the pixel unit 201. For another example, in the same pixel unit 201, the lengths of a plurality of the sub-pixels 2011 on the sides of the pixel unit 201 may be different. For another example, in the same pixel unit 201, the outline of the sub-pixel 2011 may include more than three sides of the pixel unit 201.

It should be noted that when the sub-pixel group 202 is circular, the diameter of the sub-pixel group 202 may be not less than 1 micrometer and not more than 1000 micrometers. Particularly, for the printing process, the diameter of the sub-pixel group 202 may be not less than 40 microns, and not more than 200 microns.

Specifically, for each side of each of the pixel units 201, the distance between two adjacent sub-pixels 2011 is not less than 5 microns, and not more than 200 microns.

Before step S20, the method may further comprise:

S101: forming an anode layer 30 on the substrate 10. The anode layer 30 is disposed between the substrate 10 and the pixel layer 20. The anode layer 30 comprises a plurality of anode portions 301, and the anode portions 301 are disposed opposite to the sub-pixels 2011.

Wherein, the anode layer 30 may be formed through a process of physical vapor deposition-development-wet etching. A material of the anode layer 30 may be a reflective material or a transmissive material. Specifically, when the display panel 00 is a top emission type, the anode layer 30 is made of a reflective material. When the display panel 00 is a bottom emission type, the anode layer 30 is made of a transmissive material.

Further, the display panel 00 further comprises a thin film transistor layer. When the substrate 00 does not comprise the thin film transistor layer, the thin film transistor layer is disposed between the substrate 10 and the anode layer 30. The thin film transistor layer comprises a plurality of thin film transistor units, and the thin film transistor units are disposed opposite to the anode portion 301. Specifically, a source or a drain of each thin film transistor is connected to a corresponding anode portion 301, and a voltage of the source or the drain of each the thin film transistor is controlled through a gate line and a data line to control a corresponding voltage of the anode portion 301. It can be understood that a cathode layer may be further disposed above the pixel layer 20. The cathode layer has a predetermined voltage, and the voltage or the current of the corresponding sub-pixel 2011 can be controlled by a voltage difference between each the anode portion 301 and the cathode layer, so as to control a color of light of the corresponding sub-pixel 2011. That is, in the same sub-pixel group 202, the color of the light of each the sub-pixel 2011 is independently controlled by the voltage or current of the corresponding anode portion 301.

Wherein, between the step S101 and the step 30, the method further comprises:

S102: forming a pixel definition layer 40 on the anode layer. The pixel definition layer 40 comprises a plurality of first pixel definition portions 401 and a plurality of second pixel definition portions 402. The first pixel definition portions 401 are disposed between the two adjacent anode portions 301 in the same sub-pixel group 202, and the second pixel definition portions 402 are disposed between the two adjacent sub-pixel groups 202.

A material of the first pixel definition portion 401 is an insulating material. It can be understood that, since the anode portions 301 are made of conductive material and each of the sub-pixels 2011 in the sub-pixel group 202 belongs to different pixel units 201, the anode portions 301 for controlling each of the sub-pixels 2011 should be disconnected from each other, i.e., not conductive. That is, the material of the first pixel definition portion 401 may be an insulating material. Further, it can be found through experiments that as long as the first pixel definition portion 401 is ensured to have the insulating function, that is, the sub-pixels 2011 can control the corresponding voltage or current of the corresponding anode portion 301, even if the plurality of sub-pixels 2011 in the same sub-pixel group 202 are in contact with each other, the effect of emitting light individually by each sub-pixel 2011 is not affected. It is understood that, in order to ensure an integrity of each sub-pixel group 202 and to increase the area of the sub-pixels 2011, the upper surface of the first pixel definition portion 401 is not lower than the upper surface of the sub-pixels 2011, so that the sub-pixels 2011 in the same sub-pixel group 202 are in contact with each other. Furthermore, the first pixel definition portion 401 may be made of hydrophilic material, so that the sub-pixels 2011 in the same sub-pixel group 202 may be more coherent with each other.

It is understood that the plurality of second pixel definition portions 402 fill all gaps between the plurality of sub-pixel groups 202, and the second pixel definition portions 402 are used for dividing the sub-pixel groups 202 with different colors to prevent color mixing. Further, since the material of the sub-pixel group 202 is a hydrophilic material, the second pixel definition portions 402 may be made of an organic resin material having hydrophobicity.

In an embodiment, as shown in FIG. 1, a cross-sectional shape of the first pixel definition portion 401 and the second pixel definition portion 402 may be trapezoid, and a length of an upper base of the trapezoid is less than that of the lower base. Specifically, the inclination angles on both sides of the cross-sectional pattern of the first pixel definition portion 401 and the second pixel definition portion 402 may be set to 60° or less. Thus, when a liquid organic light-emitting solution is applied, the liquid organic light-emitting solution flows toward the anode portion 103 along the side surfaces of the first pixel definition portion 401 and the second pixel definition portion 402 corresponding thereto. When the organic light-emitting solution is coated thickly, the mutual color mixing and overflow between the adjacent organic light-emitting solutions with different colors can be avoided.

The present invention provides the display panel and the manufacturing method thereof. By disposing the pixel unit having the regular M polygon, and each the inner angle of the regular M polygon is m, wherein

$$m = \frac{( M - 2 ) * π}{M} .$$

Each of the pixel units includes M sub-pixels respectively disposed at M corners of the regular M polygon. The colors of the M sub-pixels are different, the shapes and sizes of the M sub-pixels are the same, and the gap is disposed between the two adjacent sub-pixels, wherein M is a positive integer greater than 2, and

$$\frac{2 π}{m}$$

is a positive integer. Each of the sub-pixels in a same pixel unit is included in a sub-pixel group, and the sub-pixel group is a center-symmetrical figure. The sub-pixel group comprise

$$\frac{2 π}{m}$$

sub-pixels, any two of the sub-pixels in the sub-pixel group are symmetrical about the corresponding symmetry axis, each the symmetry axis passes through the center of the sub-pixel group, and the

$$\frac{2 π}{m}$$

sub-pixels in each the sub-pixel group have the same color and are disconnected from each other. That is, by splitting multiple sub-pixels in the same sub-pixel group, and then recombining the multiple sub-pixels in respective directions into corresponding multiple pixel units, the number of the pixel units can be 3 to 6 times the corresponding number in the prior art, so while maintaining sizes of current grooves, the resolution of the display panels can be improved.

In the above, various other corresponding changes and modifications can be made according to the technical solutions and technical ideas of the present invention to those skilled in the art, and all such changes and modifications are within the scope of the claims of the present invention.

1. A display panel, comprising:
a substrate and a pixel layer disposed on the substrate;
wherein the pixel layer comprises a plurality of pixel units, each of the pixel units is a regular M polygon, and each inner angle of the regular M polygon is m, wherein
$$m = \frac{( M - 2 ) * π}{M} ;$$
each of the pixel units comprise M sub-pixels, and the M sub-pixels are respectively disposed at M corners of the regular M polygon; colors of the M sub-pixels are different, shapes and sizes of the M sub-pixels are the same, and a gap is disposed between the two adjacent sub-pixels, wherein M is a positive integer greater than 2, and
$$\frac{2 π}{m}$$
is a positive integer;
wherein each of the sub-pixels in a same pixel unit is included in a sub-pixel group, and the sub-pixel group is a center-symmetrical figure; the sub-pixel group comprise
$$\frac{2 π}{m}$$
sub-pixels, any two of the sub-pixels in the sub-pixel group are symmetrical about a corresponding symmetry axis, each the symmetry axis passes through a center of the sub-pixel group, and the
$$\frac{2 π}{m}$$
sub-pixels in each the sub-pixel group have the same color and are disconnected from each other.

2. The display panel as claimed in claim 1, wherein the M is 3, each of the pixel units is a regular triangle, each of the pixel units comprises three of the sub-pixels, and the three sub-pixels are respectively disposed at three corners of the regular triangle; and wherein the sub-pixel group comprises six of the sub-pixels.

3. The display panel as claimed in claim 1, wherein the M is 4, each of the pixel units is a square, each of the pixel units comprises four of the sub-pixels, and the four sub-pixels are respectively disposed at four corners of the square; and wherein the sub-pixel group comprises four of the sub-pixels.

4. The display panel as claimed in claim 1, wherein the M is 6, each of the pixel units is a regular hexagon, each of the pixel units comprises six of the sub-pixels, and the six sub-pixels are respectively disposed at six corners of the regular hexagon; and wherein the sub-pixel group comprises three of the sub-pixels.

5. The display panel as claimed in claim 1, further comprising an anode layer disposed between the substrate and the pixel layer, wherein the anode layer comprises a plurality of anode portions, and the anode portions are disposed opposite to the sub-pixels.

6. The display panel as claimed in claim 5, further comprising a pixel definition layer disposed on the substrate, wherein the pixel definition layer comprises a plurality of first pixel definition portions, and the first pixel definition portions are disposed between the two adjacent anode portions in the same sub-pixel group.

7. The display panel as claimed in claim 6, wherein a material of the first pixel defining portion is an insulating material.

8. The display panel as claimed in claim 6, wherein the pixel definition layer further comprises a plurality of second pixel definition portions, and the second pixel definition portions are disposed between the two adjacent sub-pixel groups.

9. A display device, comprising:
a display panel, wherein the display panel comprises:
a substrate and a pixel layer disposed on the substrate;
wherein the pixel layer comprises a plurality of pixel units, each of the pixel units is a regular M polygon, and each inner angle of the regular M polygon is m, wherein
$$m = \frac{( M - 2 ) * π}{M} ;$$
each of the pixel units comprise M sub-pixels, and the M sub-pixels are respectively disposed at M corners of the regular M polygon; colors of the M sub-pixels are different, shapes and sizes of the M sub-pixels are the same, and a gap is disposed between the two adjacent sub-pixels, wherein M is a positive integer greater than 2, and
$$\frac{2 π}{m}$$
is a positive integer;
wherein each of the sub-pixels in a same pixel unit is included in a sub-pixel group, and the sub-pixel group is a center-symmetrical figure; the sub-pixel group comprise
$$\frac{2 π}{m}$$
sub-pixels, any two of the sub-pixels in the sub-pixel group are symmetrical about a corresponding symmetry axis, each the symmetry axis passes through a center of the sub-pixel group, and
$$\frac{2 π}{m}$$
the sub-pixels in each the sub-pixel group have the same color and are disconnected from each other.

10. The display device as claimed in claim 9, wherein the M is 3, each of the pixel units is a regular triangle, each of the pixel units comprises three of the sub-pixels, and the three sub-pixels are respectively disposed at three corners of the regular triangle; and wherein the sub-pixel group comprises six of the sub-pixels.

11. The display device as claimed in claim 9, wherein the M is 4, each of the pixel units is a square, each of the pixel units comprises four of the sub-pixels, and the four sub-pixels are respectively disposed at four corners of the square; and wherein the sub-pixel group comprises four of the sub-pixels.

12. The display device as claimed in claim 9, wherein the M is 6, each of the pixel units is a regular hexagon, each of the pixel units comprises six of the sub-pixels, and the six sub-pixels are respectively disposed at six corners of the regular hexagon; and wherein the sub-pixel group comprises three of the sub-pixels.

13. The display device as claimed in claim 9, further comprising an anode layer disposed between the substrate and the pixel layer, wherein the anode layer comprises a plurality of anode portions, and the anode portions are disposed opposite to the sub-pixels.

14. The display device as claimed in claim 13, further comprising a pixel definition layer disposed on the substrate, wherein the pixel definition layer comprises a plurality of first pixel definition portions, and the first pixel definition portions are disposed between the two adjacent anode portions in the same sub-pixel group.

15. The display device as claimed in claim 14, wherein a material of the first pixel defining portion is an insulating material.

16. The display device as claimed in claim 14, wherein the pixel definition layer further comprises a plurality of second pixel definition portions, and the second pixel definition portions are disposed between the two adjacent sub-pixel groups.

17. A manufacturing method of a display panel for forming a display panel according to claim 1, comprising following steps of:
providing a substrate; and
forming a pixel layer disposed on the substrate;
wherein the pixel layer comprises a plurality of pixel units, each of the pixel units is a regular M polygon, and each inner angle of the regular M polygon is m, wherein
$$m = \frac{( M - 2 ) * π}{M} ;$$
each of the pixel units comprise M sub-pixels, and the M sub-pixels are respectively disposed at M corners of the regular M polygon; colors of the M sub-pixels are different, shapes and sizes of the M sub-pixels are the same, and a gap is disposed between the two adjacent sub-pixels, wherein M is a positive integer greater than 2, and
$$\frac{2 π}{m}$$
is a positive integer;
wherein each of the sub-pixels in a same pixel unit is included in a sub-pixel group, and the sub-pixel group is a center-symmetrical figure; the sub-pixel group comprise
$$\frac{2 π}{m}$$
sub-pixels, any two of the sub-pixels in the sub-pixel group are symmetrical about a corresponding symmetry axis, each the symmetry axis passes through a center of the sub-pixel group, and the
$$\frac{2 π}{m}$$
sub-pixels in each the sub-pixel group have the same color and are disconnected from each other.

18. The manufacturing method of the display panel as claimed in claim 17, wherein before the step of forming the pixel layer disposed on the substrate further comprises: forming an anode layer on the substrate, wherein the anode layer is disposed between the substrate and the pixel layer, the anode layer comprises a plurality of anode portions, and the anode portions are disposed opposite to the sub-pixels.
